(19) United States
(12) Patent Application Publication
(10) Pub. No.: US 2025/0210416 A1
(43) Pub. Date: Jun. 26, 2025

(54) SEMICONDUCTOR DEVICE MANUFACTURING METHOD

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Etsuo HAMADA, Himeji Hyogo (JP); Ryoichi OHARA, Himeji Hyogo (JP)

(21) Appl. No.: 19/074,145

(22) Filed: Mar. 7, 2025

Related U.S. Application Data
(63) Continuation of application No. PCT/JP2024/013863, filed on Apr. 3, 2024.

(30) Foreign Application Priority Data
Aug. 7, 2023 (JP) 2023-128373

(51) Int. Cl. H01L 21/78; H01L 21/02; H01L 21/04; H01L 21/3065

(52) U.S. Cl. CPC H01L 21/78; H01L 21/02378; H01L 21/02447; H01L 21/02529; H01L 21/0475; H01L 21/3065

(57) ABSTRACT

A semiconductor device manufacturing method includes: forming an SiC layer on a single crystal SiC layer of a substrate, the substrate having a polycrystalline SiC substrate and the single crystal SiC layer provided on the second surface; forming a first insulating film and a second insulating film on the SiC layer, the first insulating film and the second insulating film being spaced apart from each other by a third width; forming a second groove by removing a first portion of the single crystal SiC layer and a second portion of the SiC layer provided on the first portion; and forming a first groove by dicing, the first groove being provided below the second groove, the first groove having a first width smaller than the second width in the first direction, the first groove extending in the second direction, and the polycrystalline SiC substrate being cut by the first groove.

### CROSS-REFERENCE TO RELATED APPLICATION

This application is based upon and claims the benefit of priority from Japanese Patent Application No. 2023-128373, filed on Aug. 7, 2023, the entire contents of which are incorporated herein by reference.

### FIELD

Embodiments of the present invention relates to a semiconductor device manufacturing method.

### BACKGROUND

SiC (silicon carbide) is expected as a material for next-generation semiconductor devices. Silicon carbide has a bandgap of about 3 times, a breakdown field strength of about 10 times, and a thermal conductivity of about 3 times that of Si (silicon). Therefore, by using SiC, it is possible to realize a semiconductor device that can operate at high temperature with low loss.

### BRIEF DESCRIPTION OF DRAWINGS

FIG. 1 is a schematic cross-sectional view of a substrate according to a first embodiment;

FIG. 2 is a schematic cross-sectional view showing steps of manufacturing a semiconductor device according to the first embodiment;

FIG. 3 is a schematic cross-sectional view showing steps of manufacturing the semiconductor device according to the first embodiment;

FIG. 4 is a schematic cross-sectional view showing steps of manufacturing the semiconductor device according to the first embodiment;

FIG. 5 is a schematic cross-sectional view showing steps of manufacturing the semiconductor device according to the first embodiment;

FIG. 6 is a schematic cross-sectional view showing steps of manufacturing the semiconductor device according to the first embodiment;

FIG. 7 is a schematic cross-sectional view showing steps of manufacturing the semiconductor device according to the first embodiment;

FIG. 8 is a schematic cross-sectional view showing steps of manufacturing the semiconductor device according to the first embodiment;

FIG. 9 is a flowchart showing steps of manufacturing the semiconductor device according to the first embodiment;

FIG. 10 is a schematic cross-sectional view showing steps of manufacturing a semiconductor device according to a second embodiment;

FIG. 11 is a schematic cross-sectional view showing steps of manufacturing the semiconductor device according to the second embodiment;

FIG. 12 is a schematic cross-sectional view showing steps of manufacturing the semiconductor device according to the second embodiment;

FIG. 13 is a schematic cross-sectional view showing steps of manufacturing the semiconductor device according to the second embodiment;

FIG. 14 is a flowchart showing steps of manufacturing the semiconductor device according to the second embodiment;

FIG. 15 is a schematic diagram of a predetermined layer in a third embodiment;

FIGS. 16A and 16B are schematic diagrams of a predetermined layer in the third embodiment;

FIG. 17 is a schematic diagram of a predetermined layer in a comparative form of the third embodiment; and

FIGS. 18A and 18B are schematic diagrams of a predetermined layer in a comparative form of the third embodiment.

### DETAILED DESCRIPTION

Hereinafter, embodiments of the invention will be described with reference to the diagrams. In addition, in the following description, the same members and the like are denoted by the same reference numerals, and the description of the members and the like once described will be omitted as appropriate.

In the following description, when the notations of n⁺, n, n⁻, p⁺, p, and p⁻ are used, these notations indicate the relative high and low of the impurity concentration in each conductivity type. That is, n⁺ indicates that the n-type impurity concentration is relatively higher than n, and n⁻ indicates that the n-type impurity concentration is relatively lower than n. In addition, p⁺ indicates that the p-type impurity concentration is relatively higher than p, and p⁻ indicates that the p-type impurity concentration is relatively lower than p. In addition, n⁺-type and n⁻-type may be simply described as n-type, p⁺-type and p⁻-type may be simply described as p-type.

The impurity concentration can be measured by, for example, SIMS (Secondary Ion Mass Spectrometry). In addition, the relative high and low of the impurity concentration can also be determined from, for example, the high and low of the carrier concentration obtained by SCM (Scanning Capacitance Microscopy). In addition, the distance such as the depth of an impurity region can be calculated by, for example, SIMS. In addition, the distance such as the width or depth of an impurity region can be calculated from, for example, an SCM image.

Hereinafter, the first conductivity type will be referred to as n-type, and the second conductivity type will be referred to as p-type.

In this specification, in order to show the positional relationship of components and the like, the upper direction of the diagram is described as “upper” and the lower direction of the diagram is described as “lower”. In this specification, the concepts of “upper” and “lower” do not necessarily indicate the relationship with the direction of gravity.

### First Embodiment

A semiconductor device manufacturing method according to the present embodiment includes: forming an SiC layer on a single crystal SiC layer of a substrate, the substrate having a polycrystalline SiC substrate with a first surface and a second surface and the single crystal SiC layer provided on the second surface; forming a first insulating film and a second insulating film on the SiC layer, the first insulating film and the second insulating film being spaced apart from each other by a third width in a first direction parallel to the second surface; forming a second groove by removing a first portion of the single crystal SiC layer and a second portion of the SiC layer provided on the first portion, the first portion and the second portion being provided below and between the first insulating film and the second insulating film, the first portion and the second portion extending in a second direction crossing the first direction and parallel to the second surface, the single crystal SiC layer and the SiC layer being cut by the second groove, the second groove extending in the second direction, the second groove having a second width smaller than the third width in the first direction, the second groove having a bottom, the polycrystalline SiC substrate being exposed at the bottom; and forming a first groove by dicing, the first groove being provided below the second groove, the first groove having a first width smaller than the second width in the first direction, the first groove extending in the second direction, and the polycrystalline SiC substrate being cut by the first groove.

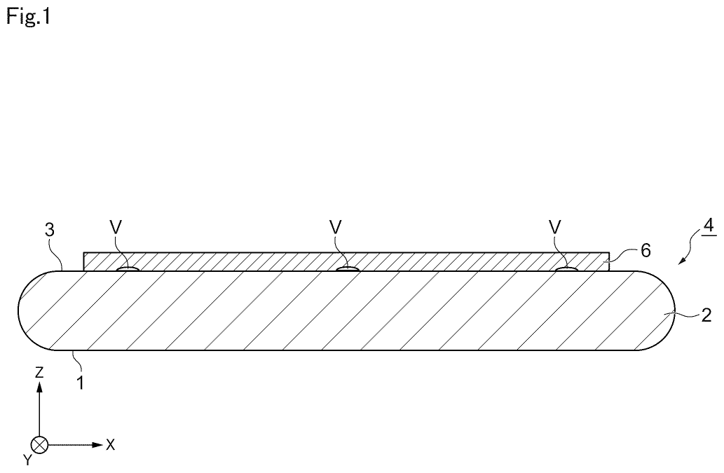

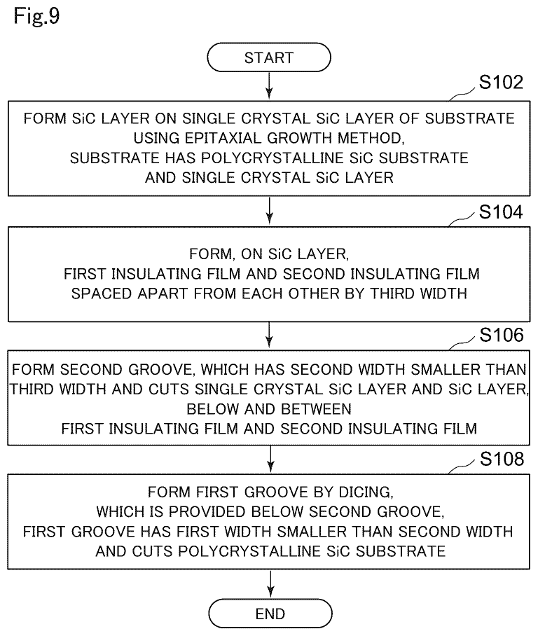

FIGS. 1 to 8 are schematic cross-sectional views showing steps of manufacturing a semiconductor device according to the present embodiment. FIG. 9 is a flowchart showing the steps of manufacturing the semiconductor device according to the present embodiment.

A semiconductor device 100 according to the present embodiment is a semiconductor chip. The semiconductor device 100 according to the present embodiment is, for example, a MOSFET (Metal Oxide Semiconductor Field Effect Transistor). However, the semiconductor device 100 is not limited to this, and may be, for example, a PIN diode or the like.

First, as shown in FIG. 1, a substrate 4 is prepared.

The substrate 4 includes a polycrystalline SiC substrate 2 and a single crystal SiC layer 6.

The polycrystalline SiC substrate 2 has a first surface 1 and a second surface 3. The second surface 3 is provided on a side opposite to the first surface 1.

Here, an X direction, a Y direction perpendicular to the X direction, and a Z direction perpendicular to the X and Y directions are defined. The first surface 1 and the second surface 3 are provided parallel to the XY plane. The X direction is an example of the first direction. The Y direction is an example of the second direction. The −X direction is an example of the third direction.

The thickness of the polycrystalline SiC substrate 2 in the Z direction is, for example, about 350 μm.

The single crystal SiC layer 6 is provided on the second surface 3 of the polycrystalline SiC substrate 2. The thickness of the single crystal SiC layer 6 in the Z direction is, for example, 0.4 μm or more and 0.7 μm or less.

The substrate 4 is, for example, a substrate in which the single crystal SiC layer 6 is bonded to the polycrystalline SiC substrate 2.

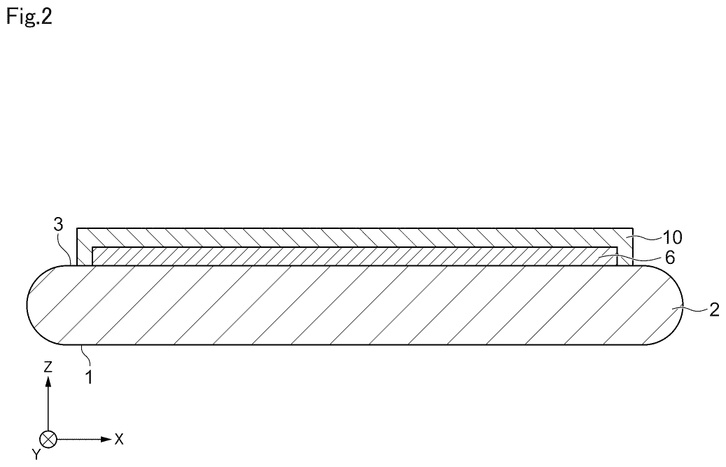

A void (vacancy) V may be formed between the polycrystalline SiC substrate 2 and the single crystal SiC layer 6. It is believed that the void (vacancy) V is formed, for example, when the polycrystalline SiC substrate 2 and the single crystal SiC layer 6 are not bonded together properly. In addition, in FIG. 2 and subsequent drawings, the void (vacancy) V between the polycrystalline SiC substrate 2 and the single crystal SiC layer 6 is not shown.

Then, an SiC layer 10 is formed on the single crystal SiC layer 6, for example, by an epitaxial growth method using a CVD method (Chemical Vapor Deposition method) (FIG. 2 and S102 in FIG. 9). The SiC layer 10 is an epitaxial SiC layer. In addition, as shown in FIG. 2, a part of the SiC layer 10 may be formed directly on the polycrystalline SiC substrate 2.

Then, a device structure of the semiconductor device 100 is formed on the SiC layer 10. For example, a conductive film 20, a conductive film 22, a conductive film 24, and a conductive film 26 are formed. For example, when the semiconductor device 100 is a MOSFET, the conductive film 20, the conductive film 22, the conductive film 24, and the conductive film 26 are source electrodes of the MOSFET. The conductive film 20, the conductive film 22, the conductive film 24, and the conductive film 26 contain a conductive material, such as Al (aluminum), Au (gold), Ag (silver), and Cu (copper).

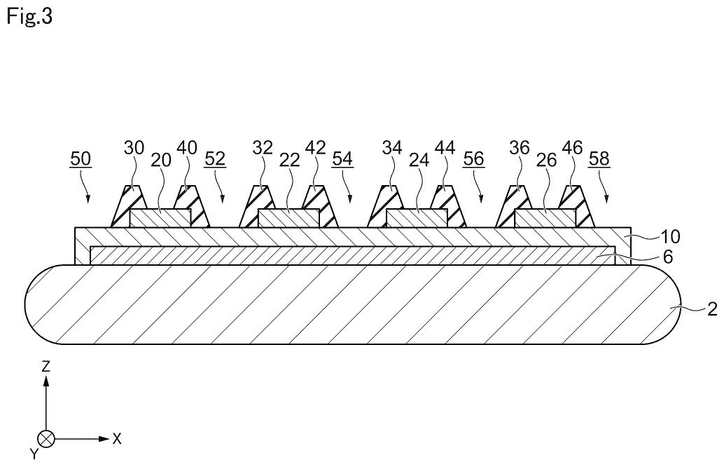

Then, an insulating film 30 and an insulating film 40 are formed on the SiC layer 10 so that the conductive film 20 is provided between the insulating film 30 and the insulating film 40. In addition, an insulating film 32 and an insulating film 42 are formed on the SiC layer 10 so that the conductive film 22 is provided between the insulating film 32 and the insulating film 42. In addition, an insulating film 34 and an insulating film 44 are formed on the SiC layer 10 so that the conductive film 24 is provided between the insulating film 34 and the insulating film 44. In addition, an insulating film 36 and an insulating film 46 are formed on the SiC layer 10 so that the conductive film 26 is provided between the insulating film 36 and the insulating film 46. The insulating film 30, the insulating film 32, the insulating film 34, the insulating film 36, the insulating film 40, the insulating film 42, the insulating film 44, and the insulating film 46 are, for example, interlayer insulating films of the semiconductor device 100. The insulating film 30, the insulating film 32, the insulating film 34, the insulating film 36, the insulating film 40, the insulating film 42, the insulating film 44, and the insulating film 46 contain an insulating material, such as polyimide (FIG. 3 and S104 in FIG. 9).

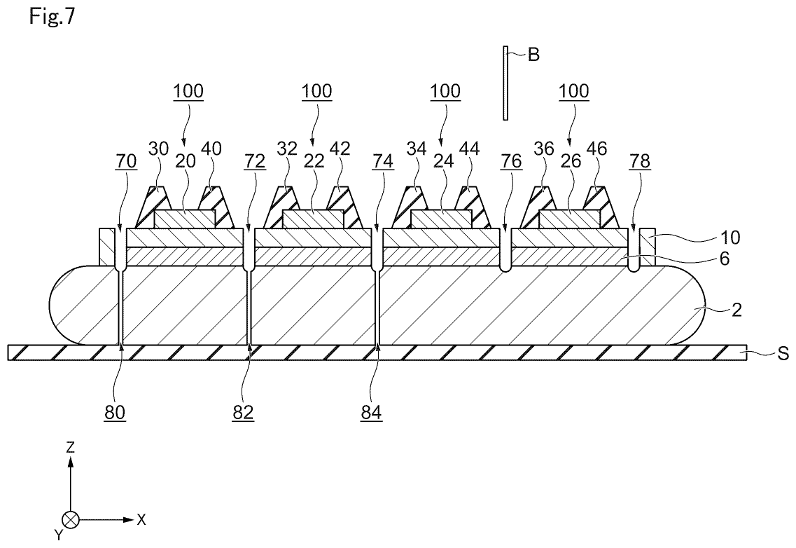

As shown in FIG. 7, which will be described later, for example, one semiconductor device 100 includes the conductive film 20, the insulating film 30, and the insulating film 40. In addition, for example, one semiconductor device 100 includes the conductive film 22, the insulating film 32, and the insulating film 42. In addition, for example, one semiconductor device 100 includes the conductive film 24, the insulating film 34, and the insulating film 44. In addition, for example, one semiconductor device 100 includes the conductive film 26, the insulating film 36, and the insulating film 46.

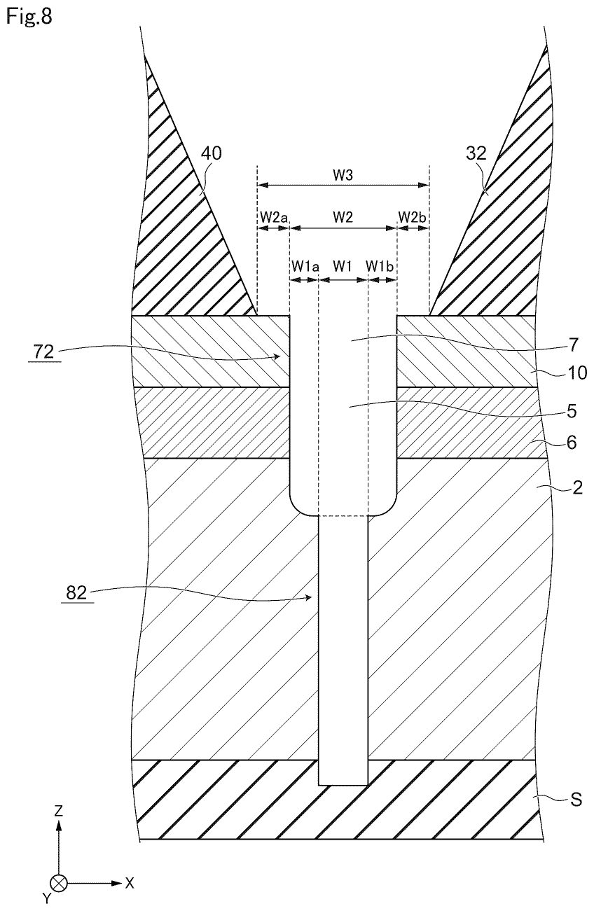

The insulating film 40 (an example of the first insulating film) and the insulating film 32 (an example of the second insulating film) are spaced apart from each other by a third width in the X direction. The spaced-apart portion between the insulating film 40 and the insulating film 32 is a dicing line 52. The insulating film 42 (an example of the first insulating film) and the insulating film 34 (an example of the second insulating film) are spaced apart from each other by the third width in the X direction. The spaced-apart portion between the insulating film 42 and the insulating film 34 is a dicing line 54. The insulating film 44 (an example of the first insulating film) and the insulating film 36 (an example of the second insulating film) are spaced apart from each other by the third width in the X direction. The spaced-apart portion between the insulating film 44 and the insulating film 36 is a dicing line 56. In addition, a dicing line 50 is provided on the −X direction side of the insulating film 30. In addition, a dicing line 58 is provided on the +X direction side of the insulating film 46. The third width is shown as “W3” in FIG. 8, which will be described later.

The dicing line 50, the dicing line 52, the dicing line 54, the dicing line 56, and the dicing line 58 are portions to be diced using, for example, a blade in a later step. The dicing line 50, the dicing line 52, the dicing line 54, the dicing line 56, and the dicing line 58 each extend in the Y direction.

In addition, similarly, dicing lines (not shown) extending in the X direction may be provided.

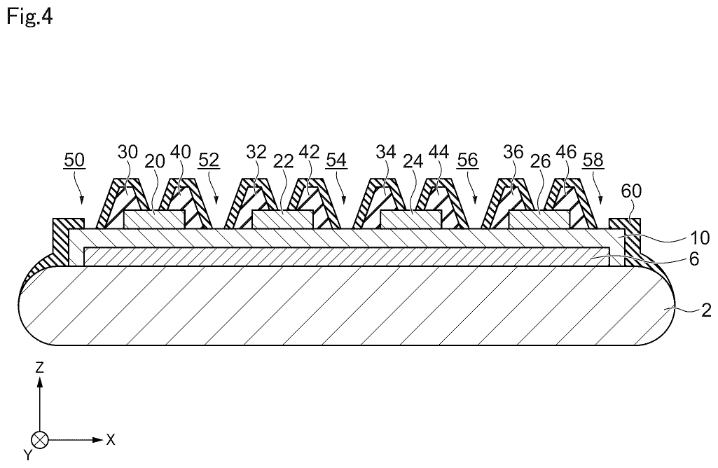

Then, a photomask (mask) 60, for example, a photoresist, is formed on the polycrystalline SiC substrate 2, the SiC layer 10, the conductive film 20, the conductive film 22, the conductive film 24, the conductive film 26, the insulating film 30, the insulating film 32, the insulating film 34, the insulating film 36, the insulating film 40, the insulating film 42, the insulating film 44, and the insulating film 46 (FIG. 4). In addition, the photomask 60 in the portions of the dicing line 52, the dicing line 54, the dicing line 56, and the dicing line 58 has openings parallel to the Y direction.

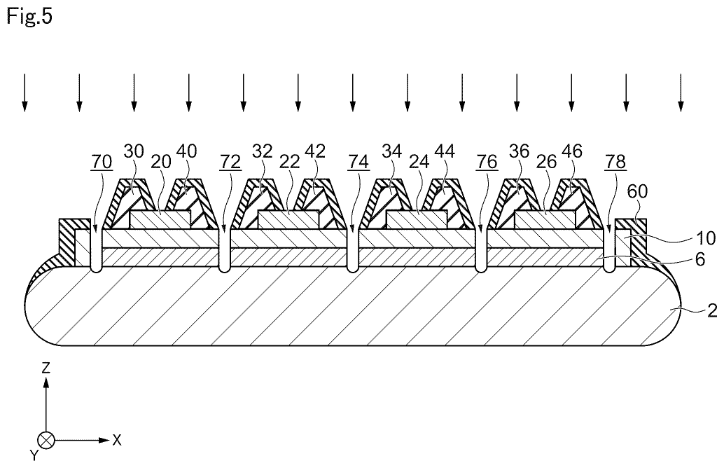

Then, using the photomask (mask) 60, a portion of the single crystal SiC layer 6 extending in the Y direction and a portion of the SiC layer 10 extending in the Y direction, which are below and between the insulating film 40 and the insulating film 32, are removed along the dicing line 52. Here, the portion of the single crystal SiC layer 6 extending in the Y direction that is removed is a first portion 5 of the single crystal SiC layer 6 shown in FIG. 8. In addition, the portion of the SiC layer 10 extending in the Y direction that is removed is a second portion 7 of the SiC layer 10 shown in FIG. 8. As a result, a second groove 72 that cuts the single crystal SiC layer 6 and the SiC layer 10 is formed (FIG. 5 and S106 in FIG. 9). The width of the second groove 72 is a second width. The second width is smaller than the third width. The second width is shown as “W2” in FIG. 8.

Similarly, below and between the insulating film 42 and the insulating film 34, a second groove 74 is formed along the dicing line 54. In addition, below and between the insulating film 44 and the insulating film 36, a second groove 76 is formed along the dicing line 56. In addition, a second groove 78 is formed along the dicing line 58. In addition, the second groove 70 is formed.

Here, the second groove 70, the second groove 72, the second groove 74, the second groove 76, and the second groove 78 are formed by using reactive ion etching (RIE) using a fluorine-based gas such as SF₆ (sulfur hexafluoride), for example. In addition, in this case, the fluorine-based gas such as SF₆ may be diluted with Ar (argon) or the like.

Here, it is preferable that the polycrystalline SiC substrate 2 is exposed at the bottoms of the second groove 70, the second groove 72, the second groove 74, the second groove 76, and the second groove 78.

In addition, the second groove 70, the second groove 72, the second groove 74, the second groove 76, and the second groove 78 may be formed by using plasma dicing, wet etching, chemical dry etching (CDE), and the like.

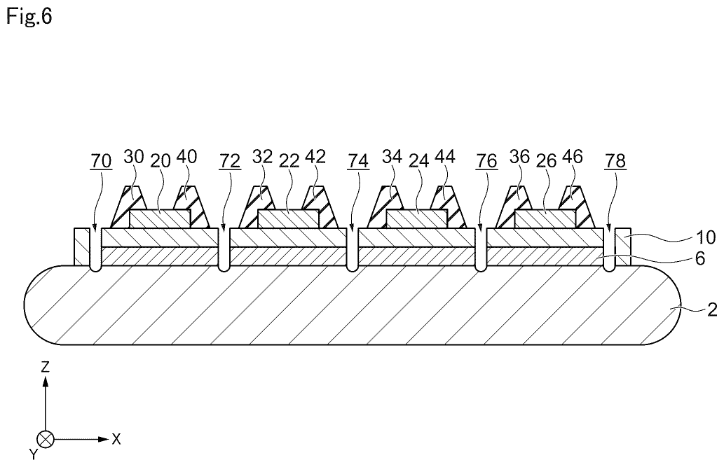

Then, the photomask 60 is removed (FIG. 6).

Then, a first groove 82 that is provided below the second groove 72, has a first width smaller than the second width in the X direction, extends in the Y direction, and cuts the polycrystalline SiC substrate 2 is formed by dicing using, for example, a blade B. Similarly, a first groove 80 is formed below the second groove 70. Similarly, a first groove 84 is formed below the second groove 74. In addition, a first groove (not shown) is also formed below the second groove 76 and the second groove 78 (FIG. 7 and S108 in FIG. 9). In addition, the first groove 82 may be formed by laser dicing or plasma dicing. The first width is shown as “W1” in FIG. 8.

In addition, here, the first surface 1 of the polycrystalline SiC substrate 2 is bonded to a dicing tape S, for example.

By peeling off each of the portions separated by the first grooves from the dicing tape S, the semiconductor device 100 according to the present embodiment is obtained.

FIG. 8 is an enlarged schematic cross-sectional view of the first groove 82 and the second groove 72.

The width of the first groove 82 in the X direction is a first width W1. The width of the second groove 72 in the X direction is a second width W2. In the X direction, the insulating film 40 and the insulating film 32 are provided so as to be spaced apart from each other by a third width W3.

It is preferable that the second width W2 is larger than the first width W1 by a width W1b in the X direction and a width W1a in the −X direction. Here, it is preferable that the width W1b and the width W1a are each 10 μm or more and 25 μm or less. Therefore, it is preferable that the second width W2 is larger than the first width W1 by 10 μm or more and 25 μm or less in both the X direction and the −X direction.

It is preferable that the third width W3 is larger than the second width W2 by a width W2b in the X direction and a width W2a in the −X direction. Here, it is preferable that the width W2a and the width W2b are each 5 μm or more and 10 μm or less. Therefore, it is preferable that the third width W3 is larger than the second width W2 by 5 μm or more and 10 μm or less in both the X direction and the −X direction.

Next, the function and effect of the present embodiment will be described.

It is difficult to manufacture a high-quality single crystal SiC substrate. Therefore, it is conceivable to manufacture a bonded substrate by thermally peeling off an SiC single crystal base material while this is bonded to the polycrystalline SiC substrate 2 to form a thin plate and bonding a single crystal SiC layer to the polycrystalline SiC substrate 2.

However, there has been a problem in that a void (vacancy) is formed between the polycrystalline SiC substrate 2 and the single crystal SiC layer 6.

When such a bonded substrate is diced, there has been a problem in that chipping or peeling occurs in the single crystal SiC layer.

In a portion where a void (vacancy) is formed between the polycrystalline SiC substrate 2 and the single crystal SiC layer, for example, the single crystal SiC layer is in a floating state above the polycrystalline SiC substrate 2. In addition, in a portion where a void (vacancy) is formed between the polycrystalline SiC substrate 2 and the single crystal SiC layer, the single crystal SiC layer and the polycrystalline SiC substrate 2 are partially bonded to each other over a very small area. When cutting such a void portion, the single crystal SiC layer, which is relatively thinner than the polycrystalline SiC substrate 2, is peeled off due to contact with the blade or frictional force, resulting in chipping or peeling. Such chipping or peeling can cause degradation in the electrical characteristics or reliability of the semiconductor device. Similar chipping or peeling can also occur when laser dicing or plasma dicing is performed.

In addition, since such a bonded substrate may have a structure of stacked substrates with different crystal structures, there has been a problem in that substrate warpage occurs due to a stress difference between the polycrystalline SiC substrate 2 and the single crystal SiC layer, distortion at the bonding interface between the polycrystalline SiC substrate 2 and the single crystal SiC layer, and the like.

Therefore, the semiconductor device manufacturing method according to the present embodiment includes: forming an SiC layer on a single crystal SiC layer of a substrate, the substrate having a polycrystalline SiC substrate with a first surface and a second surface and the single crystal SiC layer provided on the second surface; forming a first insulating film and a second insulating film on the SiC layer, the first insulating film and the second insulating film being spaced apart from each other by a third width in a first direction parallel to the second surface; forming a second groove by removing a first portion of the single crystal SiC layer and a second portion of the SiC layer provided on the first portion, the first portion and the second portion being provided below and between the first insulating film and the second insulating film, the first portion and the second portion extending in a second direction crossing the first direction and parallel to the second surface, the single crystal SiC layer and the SiC layer being cut by the second groove, the second groove extending in the second direction, the second groove having a second width smaller than the third width in the first direction, the second groove having a bottom, the polycrystalline SiC substrate being exposed at the bottom; and forming a first groove by dicing, the first groove being provided below the second groove, the first groove having a first width smaller than the second width in the first direction, the first groove extending in the second direction, and the polycrystalline SiC substrate being cut by the first groove.

According to the semiconductor device manufacturing method according to the present embodiment, the second groove for cutting the single crystal SiC layer 6 and the SiC layer 10 is formed before dicing. For this reason, chipping or peeling of the single crystal SiC layer 6 and the SiC layer 10 that occurs when forming the first groove by dicing can be suppressed. Therefore, according to the semiconductor device manufacturing method according to the present embodiment, it is possible to provide a semiconductor device manufacturing method with an improved yield.

In addition, since the single crystal SiC layer and the SiC layer are divided into small areas at the manufacturing stage, the above-described substrate warpage can be suppressed.

It is preferable that the second width W2 is larger than the first width W1 by 10 μm or more and 25 μm or less in both the X direction and the −X direction. It is preferable that the width W1a and the width W1b (FIG. 8) are larger than the kerf deviation width, such as the meandering of the cut line of the substrate, which is caused by a combination of factors such as the mechanical accuracy of the dicing device, the specifications (blade thickness and strength) of the blade B, and the cutting speed of the dicing device. The kerf deviation width is about 10 μm in both the X and −X directions. Therefore, it is preferable that the second width W2 is larger than the first width W1 by 10 μm or more in both the X direction and the −X direction. On the other hand, when the difference between the second width W2 and the first width W1 in the X direction and the −X direction is larger than 25 μm, the number of semiconductor chips that can be obtained is reduced, which is not preferable.

It is preferable that the third width W3 is larger than the second width W2 by 5 μm or more and 10 μm or less in both the X direction and the −X direction. During dry etching, the SiC layer below the insulating film may be etched back and accordingly, the insulating film may protrude like an eaves. In order to prevent this, it is preferable that the third width W3 is larger than the second width W2 by 5 μm or more in both the X direction and the −X direction. On the other hand, it is sufficient that the third width W3 is 10 μm larger than the second width W2.

It is preferable that the polycrystalline SiC substrate 2 is exposed at the bottoms of the second groove 70, the second groove 72, the second groove 74, the second groove 76, and the second groove 78. In other words, it is preferable to form a part of the second groove so as to penetrate into the polycrystalline SiC substrate 2.

For example, a case where the first groove is formed by dicing using a blade will be described. When the blade comes into contact with the void V to further cut the polycrystalline SiC substrate 2, it may not be possible to cut the polycrystalline SiC substrate 2 smoothly. For example, it is presumed that some unintended pressure is applied to the surrounding polycrystalline SiC substrate 2, single crystal SiC layer 6, and SiC layer 10 by the gas in the void V. If a part of the second groove is formed so as to penetrate into the polycrystalline SiC substrate 2, contact between the blade and the SiC layer 10, the single crystal SiC layer 6, and the void V can be reliably avoided during dicing to form the first groove.

According to the semiconductor device manufacturing method according to the present embodiment, it is possible to provide a semiconductor device manufacturing method with an improved yield.

### Second Embodiment

A semiconductor device manufacturing method according to the present embodiment includes: forming an SiC layer on a single crystal SiC layer of a substrate, the substrate having a polycrystalline SiC substrate with a first surface and a second surface and the single crystal SiC layer provided on the second surface; forming a third insulating film and a fourth insulating film on the SiC layer, the third insulating film and the fourth insulating film containing oxide, and the third insulating film and the fourth insulating film being spaced apart from each other by a second width in a first direction parallel to the second surface; forming a second groove by removing a first portion of the single crystal SiC layer and a second portion of the SiC layer provided on the first portion, the first portion and the second portion being provided below and between the third insulating film and the fourth insulating film, the first portion and the second portion extending in a second direction crossing the first direction and parallel to the second surface, the single crystal SiC layer and the SiC layer being cut by the second groove, the second groove extending in the second direction, and the second groove having the second width in the first direction; removing the third insulating film and the fourth insulating film; forming a first insulating film and a second insulating film on the SiC layer, the first insulating film and the second insulating film being spaced apart from each other by a third width larger than the second width, and the second groove being provided between the first insulating film and the second insulating film in the first direction; and forming a first groove by dicing, the first groove being provided below the second groove, the first groove having a first width smaller than the second width in the first direction, the first groove extending in the second direction, and the polycrystalline SiC substrate being cut by the first groove.

Here, the description of the content overlapping the first embodiment will be omitted.

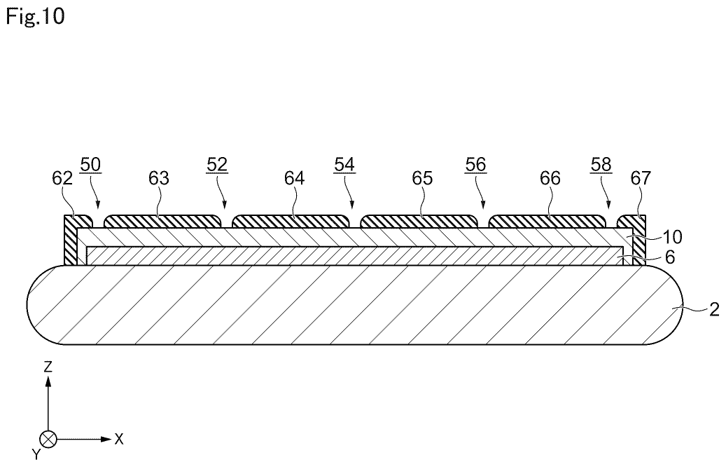

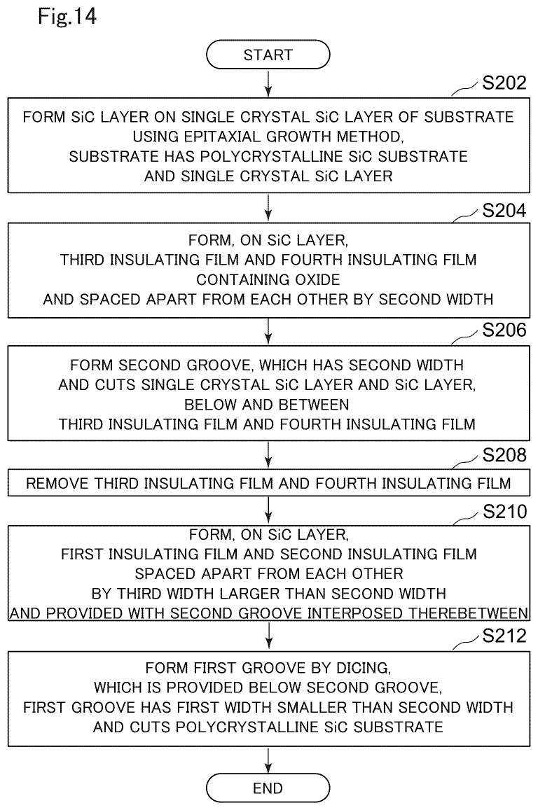

FIGS. 10 to 13 are schematic cross-sectional views showing steps of manufacturing the semiconductor device according to the present embodiment. FIG. 14 is a flowchart showing the steps of manufacturing the semiconductor device according to the present embodiment.

As in the first embodiment, an SiC layer 10 is formed on a single crystal SiC layer 6, for example, by an epitaxial growth method using a CVD method (Chemical Vapor Deposition method) (S202 in FIG. 14).

Then, an insulating film 62 containing oxide, an insulating film 63 (an example of the third insulating film) containing oxide, an insulating film 64 (an example of the fourth insulating film) containing oxide, an insulating film 65 containing oxide, an insulating film 66 containing oxide, and an insulating film 67 containing oxide are formed on the SiC layer 10. The insulating film 62 and the insulating film 63 are spaced apart from each other by a second width in the X direction. The insulating film 63 and the insulating film 64 are spaced apart from each other by the second width in the X direction. The insulating film 64 and the insulating film 65 are spaced apart from each other by the second width in the X direction. The insulating film 65 and the insulating film 66 are spaced apart from each other by the second width in the X direction. The insulating film 66 and the insulating film 67 are spaced apart from each other by the second width in the X direction (FIG. 10 and S204 in FIG. 14).

The spaced-apart portion between the insulating film 62 and the insulating film 63 is a dicing line 50. The spaced-apart portion between the insulating film 63 and the insulating film 64 is a dicing line 52. The spaced-apart portion between the insulating film 64 and the insulating film 65 is a dicing line 54. The spaced-apart portion between the insulating film 65 and the insulating film 66 is a dicing line 56. The spaced-apart portion between the insulating film 66 and the insulating film 67 is a dicing line 58.

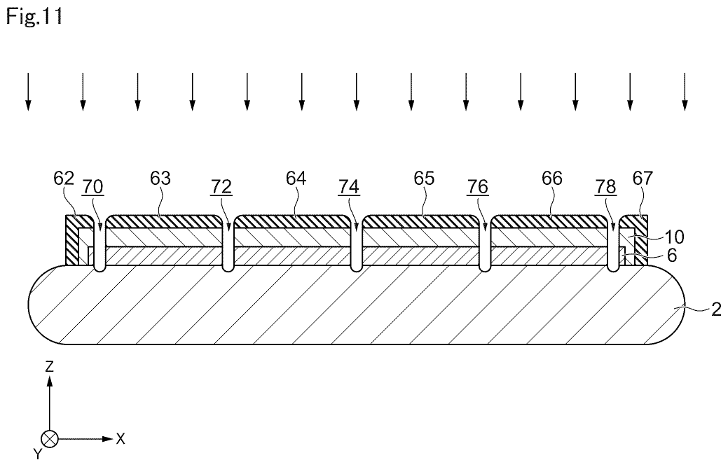

Then, using the insulating film 62, the insulating film 63, the insulating film 64, the insulating film 65, the insulating film 66, and the insulating film 67 as masks, a second groove 70 is formed in a dicing line 50, a second groove 72 is formed in a dicing line 52, a second groove 74 is formed in a dicing line 54, a second groove 76 is formed in a dicing line 56, and a second groove 78 is formed in a dicing line 58 (FIG. 11 and S206 in FIG. 14).

Here, the insulating film 62, the insulating film 63, the insulating film 64, the insulating film 65, the insulating film 66, and the insulating film 67 contain, for example, oxide. The insulating film 62, the insulating film 63, the insulating film 64, the insulating film 65, the insulating film 66, and the insulating film 67 contain, for example, silicon oxide.

Then, the insulating film 62, the insulating film 63, the insulating film 64, the insulating film 65, the insulating film 66, and the insulating film 67 are removed (S208 in S14).

Then, a device structure of the semiconductor device 100 is formed on the SiC layer 10. For example, a conductive film 20, a conductive film 22, a conductive film 24, and a conductive film 26 are formed. Then, an insulating film 30 and an insulating film 40 are formed on the SiC layer 10 so that the conductive film 20 is provided between the insulating film 30 and the insulating film 40. In addition, an insulating film 32 and an insulating film 42 are formed on the SiC layer 10 so that the conductive film 22 is provided between the insulating film 32 and the insulating film 42. In addition, an insulating film 34 and an insulating film 44 are formed on the SiC layer 10 so that the conductive film 24 is provided between the insulating film 34 and the insulating film 44. In addition, an insulating film 36 and an insulating film 46 are formed on the SiC layer 10 so that the conductive film 26 is provided between the insulating film 36 and the insulating film 46.

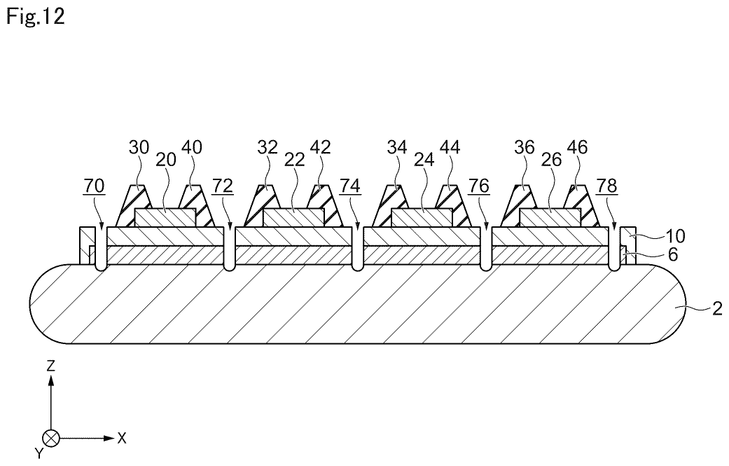

Here, the insulating film 40 (an example of the first insulating film) and the insulating film 32 (an example of the second insulating film) are spaced apart from each other by a third width in the X direction. The insulating film 42 (an example of the first insulating film) and the insulating film 34 (an example of the second insulating film) are spaced apart from each other by the third width in the X direction. The insulating film 44 (an example of the first insulating film) and the insulating film 36 (an example of the second insulating film) are spaced apart from each other by the third width in the X direction (FIG. 12 and S210 in FIG. 14).

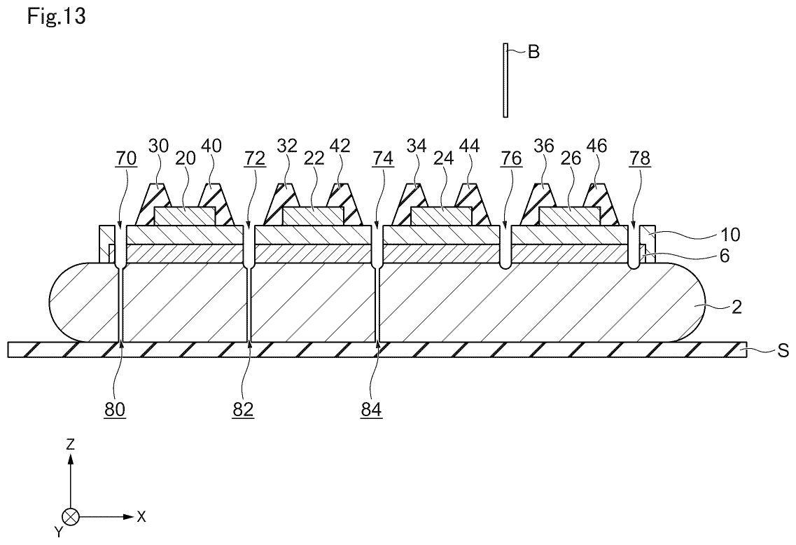

Then, a first groove 82 that is provided below the second groove 72, has a first width smaller than the second width in the X direction, extends in the Y direction, and cuts the polycrystalline SiC substrate 2 is formed by, for example, dicing using a blade B. Similarly, a first groove 80 is formed below the second groove 70. Similarly, a first groove 84 is formed below the second groove 74. In addition, a first groove (not shown) is also formed below the second groove 76 and the second groove 78 (FIG. 13 and S212 in FIG. 14).

Here, the first surface 1 of the polycrystalline SiC substrate 2 is bonded to a dicing tape S, for example.

By peeling off each of the portions separated by the first grooves from the dicing tape S, the semiconductor device 100 according to the present embodiment is obtained.

For example, since the SiC layer 10 is thick, there may be a case where it is necessary to ensure the resistance of the photomask during dry etching. In this case, a manufacturing method using the insulating film 62, the insulating film 63, the insulating film 64, the insulating film 65, the insulating film 66, and the insulating film 67 as masks is suitable, as in the semiconductor device manufacturing method according to the present embodiment.

According to the semiconductor device manufacturing method according to the present embodiment, it is possible to provide a semiconductor device manufacturing method with an improved yield.

### Third Embodiment

A semiconductor device manufacturing method according to the present embodiment is different from the semiconductor device manufacturing methods according to the first and second embodiments in that, in the step of forming the second groove, a predetermined layer having a third portion that is a part of the first portion and a fourth portion that is provided on the third portion and is a part of the second portion is formed in the second groove. Here, the description of the content overlapping the first and second embodiments will be omitted.

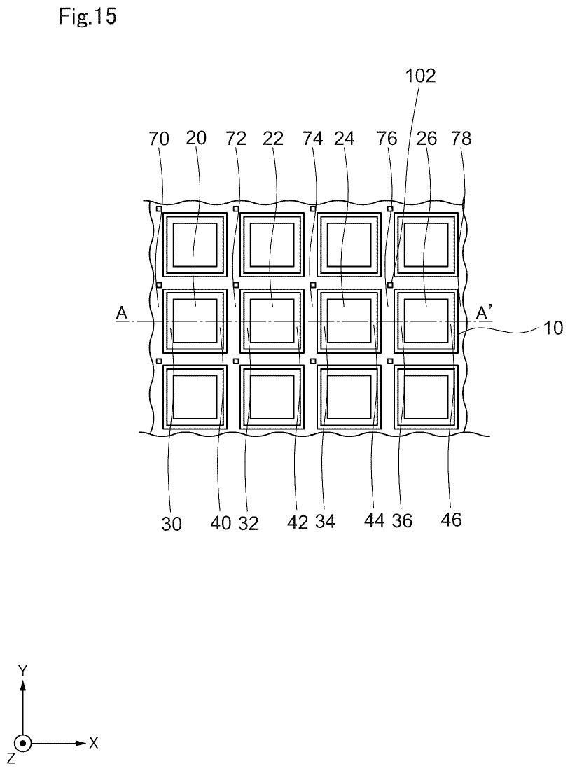

FIG. 15 is a schematic top view showing steps of manufacturing the semiconductor device according to the present embodiment. The schematic cross-sectional view shown in FIG. 6 corresponds to, for example, the cross section taken along the line A-A′ in FIG. 15.

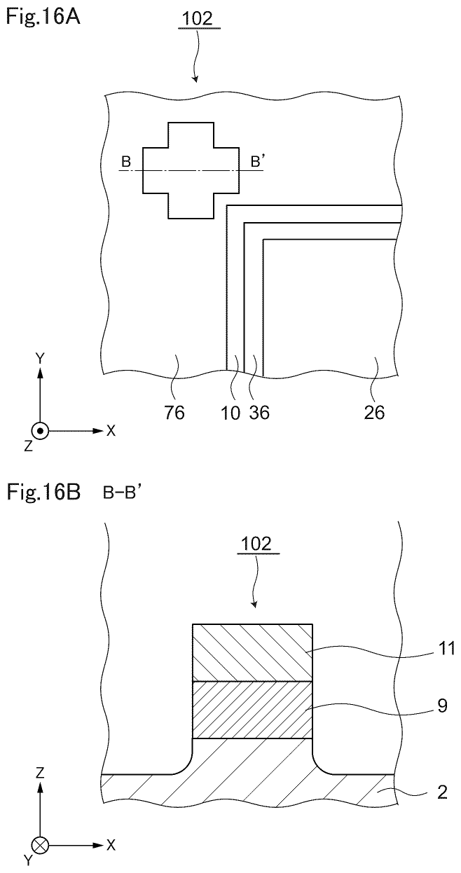

FIGS. 16A and 16B are schematic diagrams of a predetermined layer 102 in the present embodiment. FIG. 16A is a schematic top view of the predetermined layer 102 in the present embodiment. FIG. 16B is a schematic cross-sectional view of the predetermined layer 102 in the present embodiment taken along the line B-B′ in FIG. 16A.

In the step of forming the second groove 70, the second groove 72, the second groove 74, the second groove 76, and the second groove 78, the predetermined layer 102 is formed in each of the second grooves. Here, in the step of forming the second groove, a portion of the single crystal SiC layer 6 extending in the Y direction that is removed is the first portion 5 of the single crystal SiC layer 6 (FIG. 8). In addition, in the step of forming the second groove, a portion of the SiC layer 10 extending in the Y direction that is removed is the second portion 7 of the SiC layer 10 (FIG. 8). The predetermined layer 102 has a third portion 9, which is a part of the first portion 5 that is not removed but remains in the second groove, and a fourth portion 11, which is a part of the second portion that is not removed but remains in the second groove. The fourth portion 11 is provided on the third portion 9.

In addition, when a part of each of the second groove 70, the second groove 72, the second groove 74, the second groove 76, and the second groove 78 is formed in the polycrystalline SiC substrate 2, a part of the polycrystalline SiC substrate 2 around the predetermined layer 102 is also removed.

In FIG. 16A, the shape of the predetermined layer 102 is a cross shape when viewed from above. However, the shape of the predetermined layer 102 when viewed from above is not limited to the cross shape. For example, the shape of the predetermined layer 102 when viewed from above may be a rectangle.

In the dicing device, the pattern arranged on the dicing line is captured by a camera, and alignment of the substrate 4 is performed. The predetermined layer 102 is used as a reference (alignment mark) for the alignment of the substrate 4.

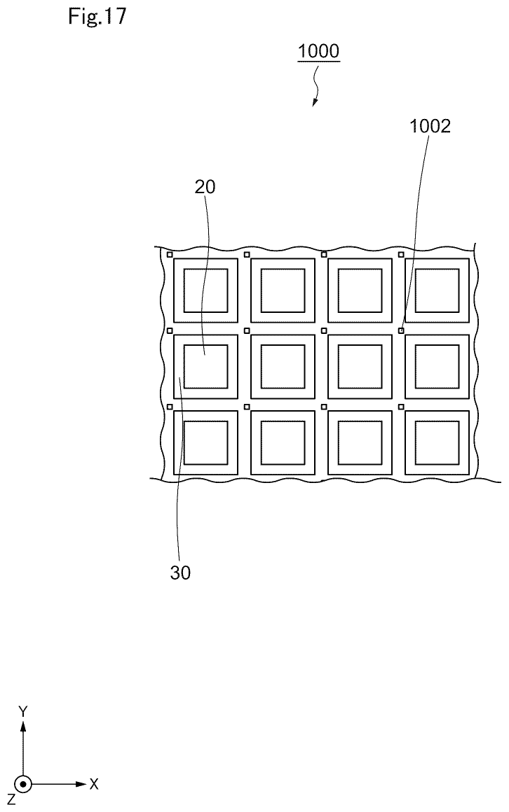

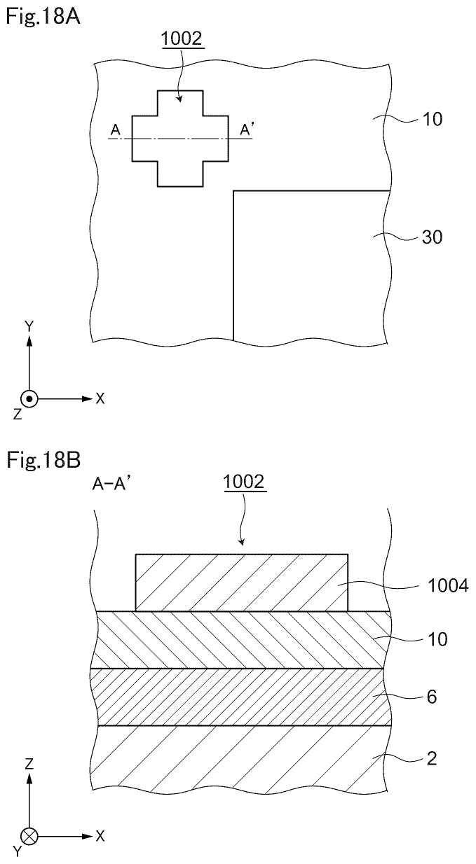

FIG. 17 is a schematic cross-sectional view showing steps of manufacturing a semiconductor device according to a comparative form of the present embodiment. FIGS. 18A and 18B are schematic diagrams of a predetermined layer 1002 in the comparative form of the present embodiment. FIG. 18A is a schematic top view of the predetermined layer 1002 in the comparative form. FIG. 18B is a schematic cross-sectional view of the predetermined layer 1002 in the comparative form taken along the line A-A′ in FIG. 18A.

The predetermined layer 1002 includes a metal layer 1004 provided on the single crystal SiC layer 6 and the SiC layer 10. Here, the metal layer 1004 contains a metal material, such as Al (aluminum). The metal layer 1004 corresponds to, for example, the conductive film 20 shown in the first and second embodiments. The single crystal SiC layer 6 and the SiC layer 10 around the metal layer 1004 are not removed by dry etching or the like.

The metal layer 1004 in the comparative form contains a conductive material such as Al, similarly to the conductive film 20. In this case, surface roughness or shape change may occur due to the influence of manufacturing steps after formation, such as sintering heat treatment, developing solutions used in photolithography, or chemicals used to remove the photoresist. In addition, if the light is diffusely reflected due to surface roughness or if the shape differs from a predetermined shape, there has been a problem in that the alignment accuracy decreases.

In the semiconductor device manufacturing method according to the present embodiment, the predetermined layer 102 having parts of the single crystal SiC layer 6 and the SiC layer 10 is formed. Therefore, the number of manufacturing steps can be reduced compared with that in the case of forming the predetermined layer 1002 having a metal layer as in the comparative form. In addition, since the predetermined layer 102 is formed of SiC, the predetermined layer 102 is less susceptible to the influence of process steps compared with the predetermined layer 1002 containing a metal material. Therefore, the alignment of the substrate 4 can be performed more satisfactorily.

According to the semiconductor device manufacturing method according to the present embodiment, it is possible to provide a semiconductor device manufacturing method with an improved yield.

While several embodiments and practical examples of the invention have been described, these embodiments and practical examples are presented as examples and are not intended to limit the scope of the invention. These novel embodiments can be implemented in various other forms, and various omissions, replacements, and modifications can be made without departing from the spirit of the invention. These embodiments or their modifications are included in the scope or spirit of the invention, and are included in the inventions described in the claims and their equivalents.

In addition, the embodiments described above can be summarized as the following technical proposals.

### (Technical Proposal 1)

A semiconductor device manufacturing method, including:
forming an SiC layer on a single crystal SiC layer of a substrate, the substrate having a polycrystalline SiC substrate with a first surface and a second surface and the single crystal SiC layer provided on the second surface;
forming a first insulating film and a second insulating film on the SiC layer, the first insulating film and the second insulating film being spaced apart from each other by a third width in a first direction parallel to the second surface;
forming a second groove by removing a first portion of the single crystal SiC layer and a second portion of the SiC layer provided on the first portion, the first portion and the second portion being provided below and between the first insulating film and the second insulating film, the first portion and the second portion extending in a second direction crossing the first direction and parallel to the second surface, the single crystal SiC layer and the SiC layer being cut by the second groove, the second groove extending in the second direction, the second groove having a second width smaller than the third width in the first direction, the second groove having a bottom, the polycrystalline SiC substrate being exposed at the bottom; and
forming a first groove by dicing, the first groove being provided below the second groove, the first groove having a first width smaller than the second width in the first direction, the first groove extending in the second direction, and the polycrystalline SiC substrate being cut by the first groove.

### (Technical Proposal 2)

The semiconductor device manufacturing method according to technical proposal 1,
wherein the second width is larger than the first width by 10 μm or more and 25 μm or less in each of the first direction and a third direction opposite to the first direction.

### (Technical Proposal 3)

The semiconductor device manufacturing method according to technical proposal 1,
wherein the third width is larger than the second width by 5 μm or more and 10 μm or less in each of the first direction and a third direction opposite to the first direction.

### (Technical Proposal 4)

The semiconductor device manufacturing method according to technical proposal 1,
wherein the second groove is formed by dry etching using a photoresist provided on the first insulating film and the second insulating film as a mask.

### (Technical Proposal 5)

The semiconductor device manufacturing method according to technical proposal 1,
wherein, in forming the second groove, a predetermined layer having a third portion and a fourth portion is formed in the second groove, the third portion being a part of the first portion, a fourth portion being provided on the third portion, and the fourth portion being a part of the second portion.

### (Technical Proposal 6)

A semiconductor device manufacturing method, including:
forming an SiC layer on a single crystal SiC layer of a substrate, the substrate having a polycrystalline SiC substrate with a first surface and a second surface and the single crystal SiC layer provided on the second surface;
forming a third insulating film and a fourth insulating film on the SiC layer, the third insulating film and the fourth insulating film containing oxide, and the third insulating film and the fourth insulating film being spaced apart from each other by a second width in a first direction parallel to the second surface;
forming a second groove by removing a first portion of the single crystal SiC layer and a second portion of the SiC layer provided on the first portion, the first portion and the second portion being provided below and between the third insulating film and the fourth insulating film, the first portion and the second portion extending in a second direction crossing the first direction and parallel to the second surface, the single crystal SiC layer and the SiC layer being cut by the second groove, the second groove extending in the second direction, and the second groove having the second width in the first direction;
removing the third insulating film and the fourth insulating film;
forming a first insulating film and a second insulating film on the SiC layer, the first insulating film and the second insulating film being spaced apart from each other by a third width larger than the second width, and the second groove being provided between the first insulating film and the second insulating film in the first direction; and
forming a first groove by dicing, the first groove being provided below the second groove, the first groove having a first width smaller than the second width in the first direction, the first groove extending in the second direction, and the polycrystalline SiC substrate being cut by the first groove.

### (Technical Proposal 7)

The semiconductor device manufacturing method according to technical proposal 6,
wherein the second width is larger than the first width by 10 μm or more and 25 μm or less in each of the first direction and a third direction opposite to the first direction.

### (Technical Proposal 8)

The semiconductor device manufacturing method according to technical proposal 6,
wherein the third width is larger than the second width by 5 μm or more and 10 μm or less in each of the first direction and a third direction opposite to the first direction.

### (Technical Proposal 9)

The semiconductor device manufacturing method according to technical proposal 6,
wherein, in forming the second groove, a predetermined layer having a third portion and a fourth portion is formed in the second groove, the third portion being a part of the first portion, a fourth portion being provided on the third portion, and the fourth portion being a part of the second portion.

What is claimed is:

1. A semiconductor device manufacturing method, comprising:
forming an SiC layer on a single crystal SiC layer of a substrate, the substrate having a polycrystalline SiC substrate with a first surface and a second surface and the single crystal SiC layer provided on the second surface;
forming a first insulating film and a second insulating film on the SiC layer, the first insulating film and the second insulating film being spaced apart from each other by a third width in a first direction parallel to the second surface;
forming a second groove by removing a first portion of the single crystal SiC layer and a second portion of the SiC layer provided on the first portion, the first portion and the second portion being provided below and between the first insulating film and the second insulating film, the first portion and the second portion extending in a second direction crossing the first direction and parallel to the second surface, the single crystal SiC layer and the SiC layer being cut by the second groove, the second groove extending in the second direction, the second groove having a second width smaller than the third width in the first direction, the second groove having a bottom, the polycrystalline SiC substrate being exposed at the bottom; and
forming a first groove by dicing, the first groove being provided below the second groove, the first groove having a first width smaller than the second width in the first direction, the first groove extending in the second direction, and the polycrystalline SiC substrate being cut by the first groove.

2. The semiconductor device manufacturing method according to claim 1,
wherein the second width is larger than the first width by 10 μm or more and 25 μm or less in each of the first direction and a third direction opposite to the first direction.

3. The semiconductor device manufacturing method according to claim 1,
wherein the third width is larger than the second width by 5 μm or more and 10 μm or less in each of the first direction and a third direction opposite to the first direction.

4. The semiconductor device manufacturing method according to claim 1,
wherein the second groove is formed by dry etching using a photoresist provided on the first insulating film and the second insulating film as a mask.

5. The semiconductor device manufacturing method according to claim 1,
wherein, in forming the second groove, a predetermined layer having a third portion and a fourth portion is formed in the second groove, the third portion being a part of the first portion, a fourth portion being provided on the third portion, and the fourth portion being a part of the second portion.

6. A semiconductor device manufacturing method, comprising:
forming an SiC layer on a single crystal SiC layer of a substrate, the substrate having a polycrystalline SiC substrate with a first surface and a second surface and the single crystal SiC layer provided on the second surface;
forming a third insulating film and a fourth insulating film on the SiC layer, the third insulating film and the fourth insulating film containing oxide, and the third insulating film and the fourth insulating film being spaced apart from each other by a second width in a first direction parallel to the second surface;
forming a second groove by removing a first portion of the single crystal SiC layer and a second portion of the SiC layer provided on the first portion, the first portion and the second portion being provided below and between the third insulating film and the fourth insulating film, the first portion and the second portion extending in a second direction crossing the first direction and parallel to the second surface, the single crystal SiC layer and the SiC layer being cut by the second groove, the second groove extending in the second direction, and the second groove having the second width in the first direction;
removing the third insulating film and the fourth insulating film;
forming a first insulating film and a second insulating film on the SiC layer, the first insulating film and the second insulating film being spaced apart from each other by a third width larger than the second width, and the second groove being provided between the first insulating film and the second insulating film in the first direction; and
forming a first groove by dicing, the first groove being provided below the second groove, the first groove having a first width smaller than the second width in the first direction, the first groove extending in the second direction, and the polycrystalline SiC substrate being cut by the first groove.

7. The semiconductor device manufacturing method according to claim 6,
wherein the second width is larger than the first width by 10 μm or more and 25 μm or less in each of the first direction and a third direction opposite to the first direction.

8. The semiconductor device manufacturing method according to claim 6,
wherein the third width is larger than the second width by 5 μm or more and 10 μm or less in each of the first direction and a third direction opposite to the first direction.

9. The semiconductor device manufacturing method according to claim 6,
wherein, in forming the second groove, a predetermined layer having a third portion and a fourth portion is formed in the second groove, the third portion being a part of the first portion, a fourth portion being provided on the third portion, and the fourth portion being a part of the second portion.
